(19) United States
(12) Patent Application Publication
(10) Pub. No.: US 2021/0050192 A1
(43) Pub. Date: Feb. 18, 2021

(54) MAGNETRON SPUTTERING DEVICE

(71) Applicant: Hartmetall-Werkzeugfabrik Paul Horn GmbH, Tuebingen (DE)

(72) Inventor: Bastian Gaedike, Neuhausen auf den Fildern (DE)

(21) Appl. No.: 17/087,781

(22) Filed: Nov. 3, 2020

Related U.S. Application Data
(63) Continuation of application No. PCT/EP2019/060913, filed on Apr. 29, 2019.

(30) Foreign Application Priority Data
May 23, 2018 (DE) 10 2018 112 335.3

(51) Int. Cl. H01J 37/34; C23C 14/35; C23C 14/34; H01J 37/32

(52) U.S. Cl. CPC H01J 37/3405; C23C 14/35; C23C 14/3414; H01J 2237/20214; H01J 37/3429; H01J 37/3467; H01J 37/32752; C23C 14/3485

(57) ABSTRACT

A magnetron sputtering device comprising a substrate; a target which forms a cathode in a DC electric field and comprises an electrically conductive mixture for coating the substrate; an anode in the DC electric field; a reaction chamber in which the target and the substrate are arranged. The target is spaced apart from the substrate. The voltage source is configured to generate the DC electric field between the cathode and the anode. The mixture comprises a first material and a second material. The substrate comprises a third material. The first material is an electrically non-conductive solid. The second material is an electrically conductive solid. The third material is an electrically conductive solid.

### CROSS-REFERENCE TO RELATED APPLICATIONS

This application is a continuation of international patent application PCT/EP2019/060913, filed on Apr. 29, 2019 designating the U.S., which international patent application has been published in German language and claims priority from German patent application DE 10 2018 112 335.3, filed on May 23, 2018. The entire contents of these priority applications are incorporated herein by reference.

### BACKGROUND

This disclosure relates to a magnetron sputtering device and a magnetron sputtering method.

Exemplary magnetron sputtering devices are disclosed in DE 102014 105 947 A1, DE 11 2008 000 702 T5 and EP 3 041 026 B1.

The term “sputtering”, which is derived from the English verb “to sputter”=“to atomize”, is understood to mean a physical process in which atoms are released from a solid, a so-called target, by being bombarded with high-energy ions and thereby change to gas phase. The released atoms coat a body and settle on its surface as a thin layer. The body to be coated is generally referred to as the “substrate”. In technical applications, the physical process is used, for example, for coating cutting tools, tool holders and forming tools.

This type of coating process is also known as “sputter deposition” and belongs to the group of vacuum-based PVD processes. The abbreviation PVD refers to physical vapour deposition. The coating usually serves to increase the resistance, wear protection and mechanical hardness.

In physical vapor deposition, the starting material is transferred into the gas phase. The atoms released from the target are accelerated by an energy input to the substrate to be coated and are deposited on the surface of the substrate as a boundary layer. In a PVD process, the material to be deposited, i.e. the target material, is usually present as a solid and is usually arranged in an evacuated coating chamber, also known as a reaction chamber. In this reaction chamber, the substrate to be coated is spaced apart from the target.

For example, energy is applied by applying a DC electric field between the target and an anode, wherein the target forms the negatively charged cathode in the DC electric field. In this case, the reaction chamber is filled with an inert process gas, which is brought into the ionized state by the energy input of the DC electric field (plasma formation). The positively charged process gas ions are accelerated by the DC electric field towards the positively charged target and through this “bombardment”, i.e. through physical shock pulse transmission, knock atoms of the target material out of its surface, which subsequently move towards the substrate and coat its surface. Thus, a continuous current of positively charged ions hits the target, which is why the process is also known as DC sputtering.

In a special case of DC sputtering, a magnetic field is generated behind the target by one or more electric or permanent magnets in addition to the electric DC field between cathode and anode, which is why this process is also called “magnetron sputtering”.

Due to the superposition of the DC electric field with the magnetic field, the ions of the process gas do not move parallel to the electric field lines, but are deflected by the Lorentz force onto a spiral path or helical path on their way to the target surface, which causes the individual ions to cover a longer distance until they hit the target surface. This longer path increases the probability of further collisions between ionized process gas ions and non-ionized process gas ions. In other words, the magnetic field increases the impact ionization and with it the total number of ionized process gas atoms. In particular, this results in an increase of the sputtering rate, wherein the sputtering rate is the number of released atoms of the target material. Thus, higher coating rates can be realized without increasing the process pressure. An increase of the process pressure also leads to an increase of the ionization rate, since the momentum of the individual process gas ions can be increased by higher pressure conditions inside the reaction chamber. Thus, magnetron sputtering can improve layer growth, homogeneity and/or layer properties on the substrate surface compared to simple cathode sputtering. The increase of the sputtering rate leads to less scattering of the material on its way to the substrate and to a denser (less porous) surface layer on the substrate surface.

The disadvantage of this process, however, is that due to the operating principle, i.e. the DC electric field between target and anode, only electrically conductive materials can be used as target or coating material. If an electrically insulating material is used as target material, an electrically insulating boundary layer is formed on the anode surface when the atoms of this insulating material are deposited. This anode surface can be, for example, the surface of the substrate or the surface of a sacrificial sheet that is connected as an anode. Through this boundary layer, the otherwise electrically conductive anode loses its electrically conductive properties and thus its anode function in the DC electric field. This phenomenon is scientifically known as the “disappearing anode effect” and prevents the deposition of many technically interesting materials (e.g. ceramics such as aluminum oxide). Furthermore, this effect can destroy an arrangement or at least lead to a termination of the coating process. This phenomenon can also occur in reactive PVD coating processes where a reactive gas is present in the reaction chamber in addition to the process gas. If, for example, metals (e.g. aluminum or zirconium) are reactively processed in such a reactive PVD process by adding oxygen, electrically non-conductive layers are created through which the anode can “disappear”.

However, especially when coating tools, tool holders or the like, it is often advantageous to use electrically non-conductive solids, such as technical ceramics, as coating material, since these materials have a high hardness, high thermal resistance, good thermal conductivity, high chemical resistance and corrosion resistance. The term “technical ceramics” is used herein to refer to an inorganic non-conductive solid.

Thus, there is a fundamental technical problem that with the known DC magnetron sputtering devices, no electrically non-conductive materials can be used to coat a substrate without the risk of a “disappearing anode effect”.

A technical possibility to coat substrates with an electrically non-conductive material is provided by the so-called alternating current dual magnetron sputtering. Between the two electrodes, e.g. between the target and the substrate, an alternating current is switched back and forth, by means of which the substrate surface is cleaned each time the direction of the current is reversed, thus preventing the “disappearing anode effect” [Source: http://www.semicore.com/news/97-what-is-mf-ac-sputtering; accessed on Apr. 26, 2018]. As an essential difference to DC magnetron sputtering, this coating process requires an AC voltage or AC electric field, which makes the overall design of the device technically much more complex and voluminous and thus much more cost-intensive and does therefore not represent an optimal solution for the technical problem.

The above-mentioned DE 10 2014 105 947 A1 shows an exemplary DC magnetron sputtering device or a process for depositing a thin piezoelectric film on an acoustic resonator. The target consists of electrically conductive aluminum, which is doped with a rare earth element that is also electrically conductive. This publication mainly deals with the task of designing a magnetic field in favor of the piezoelectric properties of the resonator coating. However, the publication does not solve the technical problem described above, but explicitly mentions that the target is made of an electrically conductive material.

The above-mentioned DE 11 2008 000 702 T5 does not solve the above-mentioned technical problem of the disappearing anode effect either. A magnetron sputtering device is described, which is used for coating liquid crystal display substrates or semi-conductor substrates, wherein this publication deals with the positioning of the magnets within the device and thus refers to a different technical area.

In the above-mentioned EP 3 041 026 B1, a gas inlet for a vacuum chamber of a magnetron sputtering device is provided, by which the distribution of a mixed gas (process gas+reactive gas) is to be harmonized after entry into the vacuum chamber.

### SUMMARY

It is an object to provide a magnetron sputtering device and a magnetron sputtering method in which the substrate can be coated with an electrically non-conductive material without an occurrence of the “disappearing anode effect”.

According to an aspect, a magnetron sputtering device is presented, which comprises:
a substrate;
a sintered or hot-pressed target which forms a cathode in a DC electric field and comprises an electrically conductive mixture for coating the substrate;
an anode in the DC electric field;
a reaction chamber in which the target and the substrate are arranged, wherein the target is arranged spaced apart from the substrate; and
a voltage source configured to generate the DC electric field between the cathode and the anode;

wherein the mixture comprises a first material and a second material, wherein the first material is an electrically non-conductive solid, and wherein the second material is an electrically conductive solid selected from the group consisting of a boride, a carbide, a nitride, and mixtures thereof; and

wherein the substrate comprises a third material which is an electrically conductive solid.

According to another aspect, a magnetron sputtering method is presented, which comprises the steps of:
providing a substrate;
providing a sintered or hot-pressed target which forms a cathode in a DC electric field and comprises an electrically conductive mixture for coating the substrate, wherein the mixture comprises a first material and a second material, wherein the first material is an electrically non-conductive solid, and wherein the second material is an electrically conductive solid from the group consisting of a boride, a carbide, a nitride, and mixtures thereof;
providing an anode in the DC electric field;
arranging the target and the substrate in a reaction chamber, wherein the target is arranged spaced apart from the substrate, wherein the substrate comprises a third material, wherein the third material is an electrically conductive solid;
introducing a process gas into the reaction chamber; and
generating the DC electric field between the cathode and the anode.

With the herein presented device and method, it is possible to coat a substrate with an electrically non-conductive solid despite DC magnetron sputtering without an occurrence of the disappearing anode effect. Until now, this was only possible with the much more complex and expensive AC magnetron sputtering. This AC magnetron sputtering is often referred to as MF magnetron sputtering. However, the herein presented device and method enable to make the target electrically conductive by adding an electrically conductive material (second material) and to continue to ensure this electrical conductivity even after the atoms of the target have been deposited on the substrate surface. Thus, the substrate can be coated in a simple and cost-effective way with a technical ceramic, for example, which creates numerous advantageous coating properties. The layer quality and layer properties of the substrate coating are largely determined by the mechanical and thermal properties of the electrically non-conductive material (first material). The second material is only added to produce the electrical conductivity. Therefore, the mixture intended for the target consists preferably of a larger proportion of the first material. The proportion of the second material, on the other hand, is preferably chosen to be as low as possible, i.e. only as high as necessary to produce the desired electrical conductivity of the target mixture. In such a case, the properties of the second material only lead to minor, technically tolerable changes in the coating on the substrate.

A further advantage of the herein presented device and method is that conventional magnetron sputtering devices already in use can be used without the need for an expensive and complex retrofit or conversion, since only the target has to be exchanged.

Furthermore, there is a further advantage compared to the above-mentioned AC magnetron sputtering device, since the presented magnetron sputtering device is time invariant and thus easier to handle.

In the most general terms, the substrate is the object to be coated. In this application preferably any kind of tools, tool parts, cutting tools, forming tools, tool holders and sections of tool holders are called substrate. It is advantageous, but not mandatory, that the substrate in the reaction chamber can be arranged, for example, on a substrate holder or reversibly detachably fixed to it.

In the present context, a target is understood to be a solid body that can basically have any kind of geometric shape. In practice, however, targets in the form of a rectangle or circle have become established, wherein the target can be advantageously arranged on a target holder within the reaction chamber. Such a target holder can, for example, be used as a mounting platform during the coating process, on which mounting platform the target can be reversibly detachably fixed.

The term “reaction chamber” refers to the housing or the working chamber or the working volume of the magnetron sputtering device in which the target is arranged spaced apart from the substrate. Advantageously, the reaction chamber comprises, for example, a vacuum pump to create a vacuum in its interior. Advantageously, the reaction chamber also comprises a gas inlet opening through which a process gas can be introduced after the vacuum has been generated, i.e. after the air has been removed from the interior of the reaction chamber. Preferably, the process gas is a noble gas, i.e. a gas which is chemically inert and therefore does not react with one or more reaction partners.

The voltage source supplies an electrical voltage or a potential difference between its connection points, e.g. realized by connecting terminals or electrical outputs. Basically, the voltage depends only slightly on the electric current, which is taken from the voltage source. The supplied electrical voltage is ideally independent of the respective connected consumer. In this case the voltage source is a DC voltage source. This means that the electrical output of the DC voltage source, which delivers a negative voltage, is connected to the target via a cable connection. The electrical output, which supplies a positive voltage or a zero potential (ground), is connected to the anode via a cable connection. It is to be mentioned here that for safety reasons, grounding of the arrangement is advantageously located at the reaction chamber.

The target comprises a first material and a second material, which in other words means that the target consists of at least a first and a second material. The target thus comprises a mixture or a material composition consisting of at least the first material and the second material, but may also comprise other materials, e.g. carrier materials. The target is sintered or hot-pressed by which it is possible to combine two different raw materials or resources, which are preferably present in powder form or as pellets, i.e. as solids, before production, with each other in a solid body.

It is to be also noted that the third material or substrate material is different from the second material. This means that the chemical composition of the third material differs from that of the second material. Only a changed morphology or crystal lattice structure (e.g. cubic space-centered, cubic face-centered or hexagonal density-packed) is not yet sufficient for the difference between the second material and the third material.

In the case at hand, the electrical conductivity, which is also called conductivity, is the physical quantity indicating the ability of a substance to conduct electric current. In electrical engineering, electrical conductivity is often given as the reciprocal of the resistivity of a substance. This resistance is usually specified with the SI unit Ohmmeter (Ωm). The SI unit of electrical conductivity is given as Siemens per meter (S/m).

Basically, the substances of the periodic table can be divided into four groups with regard to electrical conductivity. A distinction is made between superconductors, conductors, semiconductors and non-conductors. Superconductors are materials in which the electrical resistance drops to almost 0 below a material-dependent transition temperature, and the electrical conductivity thus becomes almost infinitely large. At an ambient temperature of 25° C., conductors or conducting materials have an electrical conductivity of >106 S/m. In the group of semiconductors, the electrical conductivity depends on the purity of the material. In the group of non-conductors or insulators, the electrical conductivity is usually specified as <10-8^{S/m}.

Physically speaking, the electrical conductivity can also be explained by the so-called band model. In this model, the energy properties of the electrons of different materials are generally divided into a position within a so-called valence band and a position within a so-called conduction band. Between the valence band and the conduction band there is a so-called band gap, with which essentially the electrical conductivity of a material can be explained. For example, if a material comprises a large band gap, it is considered electrically non-conductive or an insulator. If, on the other hand, a material comprises a very small or no band gap, i.e. the conduction band overlaps with the valence band or is directly connected to it, the material is considered to be electrically conductive. This property is especially valid for metals. In insulators, all electrons are located within the valence band and can only be lifted into the conduction band by a very high energy input. With electrically conductive materials, either all or at least a large number of the electrons are within the conduction band, making these materials electrically conductive without any additional energy input.

In the present case, it seems reasonable to define a solid as electrically conductive if it has an electrical conductivity of >10⁻³ S/m at an ambient temperature of 25° C. In contrast, a solid is to be considered electrically non-conductive if it has an electrical conductivity of <10⁻³ S/m at an ambient temperature of 25° C.

In a refinement, the first material has a first volumetric portion ΔV₁ and the second material has a second volumetric portion ΔV₂, wherein it applies: ΔV₁≥ΔV₂, preferably ΔV₁≥1.5 ΔV₂.

It shall be mentioned again at this point that the addition of the second material is only done to ensure the electrical conductivity of the coating. The advantageous mechanical and thermal properties of the coating are preferably determined by the material properties of the first material. For this reason, it is advantageous to add the second material in a volumetric proportion that is smaller than the volumetric proportion of the first material. For clarification of the equation ΔV₁≥1.5 ΔV₂, it should be mentioned that a preferred mixture contains at least 60 volume percent of the first material and at most 40 volume percent of the second material.

In a refinement, the first material is a first inorganic solid.

An inorganic solid is a substance from the periodic table, which is present in a solid state up to a temperature of at least 150° C. In addition, an inorganic material is to be understood as a material that has no living nature.

In a further refinement, the first inorganic solid is a carbide, a nitride and/or an oxide.

Carbides and nitrides are characterized by very strong bond energies between the atoms, which lead to high chemical and thermal stability, hardness and strength, but at the same time to lower ductility and quite high brittleness. The high bonding energy is represented on the atomic level by a high proportion of covalent bonds and a low proportion of ionic bonds.

With oxides, however, the ionic bonds dominate. Oxides, however, are also characterized by a high hardness, a high wear resistance and a good heat resistance, but are more brittle than most common carbides and are therefore used in the machining technology preferably for coatings. In addition, oxides exhibit a high corrosion resistance up to temperatures of >1000° C.

In a further refinement, the first inorganic solid is a metal oxide.

Metal oxides are compounds of a metal and oxygen and are known for their advantageous properties as coating materials. In case of metal oxides, ion bonds also dominate. Additionally, they are characterized (like oxides) by a high hardness, a high wear resistance and a good heat resistance.

In a further refinement, the metal oxide is a zirconium oxide (ZrO₂), an aluminum oxide (Al₂O₃) or a titanium oxide (TiO₂).

An advantage of these metal oxides as a coating in the machining technology is their high hardness and heat resistance as well as their high chemical and thermal resistance. They are also highly resistant to corrosion and can still be used at high temperatures in applications up to 1000° C. Also the metal oxide aluminum titanate (Al₂TiO₅) can be used as a coating element in the machining technology.

In a further refinement, the second material is a second inorganic solid. The second inorganic solid is different from the first inorganic solid. The difference lies particularly, but preferably not exclusively, in the electrical conductivity properties.

In a further refinement, the second inorganic solid is an elemental metal, a boride, a carbide and/or a nitride. With this limitation, special attention shall be paid to the electrical conductivity of the second material, wherein only electrically conductive borides, carbides and/or nitrides can be used as the second material. Elementary metals always have this required electrical conductivity.

In a further refinement, the second inorganic solid is a carbide.

Carbides refer to a group of substances whose chemical compound is given by an element (E) and carbon (C) with the general structural formula EₓC_{y}. Both salt-like and metallic compounds belong to this group. In the present case, particularly the metallic compounds are of advantage and are characterized by a high mechanical and thermal stability as well as a high melting point (3000° C. to 4000° C.).

In a further refinement, the carbide is tungsten carbide (WC), niobium carbide (NbC), hafnium carbide (HfC), tantalum carbide (TaC), titanium carbide (TiC), molybdenum carbide (MoC) and/or chromium carbide (Cr₃C₂).

Tungsten carbide (WC) has a high hardness value as well as a melting point of 2785° C. In general, tungsten carbide is the main component of many carbide types and is mainly used for machining tools and as a material for heavy-duty components or forming tools. Titanium carbide (TiC) is an inorganic chemical compound of the elements titanium and carbon. Additionally, it has a very good electrical conductivity and is stable in air up to a temperature of 800° C. It is also characterized by a particularly high hardness value of up to 4000 HV (Vickers hardness). The material is particularly well known as a coating material for cutting inserts, milling tools, broaches, forming tools, saw blades and the like. Molybdenum carbide is an intermetallic compound just like chromium carbide. Both materials can be used as a basis for corrosion-resistant carbide alloys. Niobium carbide (NbC) is particularly advantageous as a material for coating, as this carbide has a much lower purchase price compared to tungsten carbide. Additionally, it has very similar mechanical properties to WC, but has a lower density. Other advantageous metallic carbides are tantalum carbide (TaC) and hafnium carbide (HfC).

In a further refinement, the third material is carbide, cermet, cubic boron nitride or steel. These materials are particularly used in the manufacture of tool holders and cutting tools for machining, e.g. for cutting inserts, turning, milling, drilling, reaming and finishing tools.

In a further refinement, the voltage source is configured to generate the DC electric field by means of energy pulses.

Magnetron sputtering devices, in which the DC electric field is provided by energy pulses, are also known as high-energy pulse magnetron sputtering devices (HiPIMS). This refinement has the advantageous effect that higher power can be applied to the cathode, by means of which the ionization of the process gas (i.e. plasma formation) may be improved. The target material (mixture of the first and second material) is more strongly ionized by the high-energy pulses, resulting in significantly denser and more homogeneous layers when forming layers on the substrate, i.e. the coating of the substrate surface is optimized. The energy pulses typically have a pulse length of between 1 μs and 150 μs and have particularly advantageous powers>1 MW. Due to these very high powers at the cathode, significantly higher degrees of ionization of the target material can be achieved. This high degree of ionization can significantly change the properties of the growing layer on the substrate via the modified growth mechanisms and can, for example, contribute to an increased adhesion of the coating atoms on the substrate surface.

In a further refinement, the voltage source is configured to generate energy pulses with a power>0.1 MW, preferably >0.5 MW, particularly preferably >1 MW.

In a further refinement, the voltage source is configured to apply a negative bias voltage to the substrate.

When the bias voltage is applied to the substrate, the substrate is arranged electrically isolated from the reaction chamber. Advantageously, in this case the reaction chamber or a part of the reaction chamber serves as anode and/or zero potential or ground for the magnetron sputtering device. Preferably, a negative voltage or potential of −50 to −200V is applied to the substrate, wherein the bias voltage can in principle also be below or above the previously mentioned interval. Due to this substrate bias voltage the ion energy of the partially ionized plasma, which is generated by the energy input of the DC electric field between the cathode and the anode, is increased. The bias voltage results in an ion bombardment of the substrate. With a very high ion bombardment, loosely bound surface contaminants on the substrate surface are removed and the substrate surface is also roughened. This effect is also used, for example, in an advantageous etching process before coating the substrate, in order to improve the coating adhesion. With a moderate ion bombardment (between 50 and 150 V bias voltage) during the sputtering process, the movement speed of the target material's atoms in the gas phase is increased. This has positive effects on the layer structure in advantageous applications. Advantages resulting from the application of a bias voltage can be, for example, an increase of the particle energy (e.g. of the atoms of the mixture), an increase of the layer density, an increase of the compressive stress and/or an increase of the hardness of the substrate coating.

In a further refinement, the substrate forms the anode. This means that the substrate is connected to the voltage source or is placed on a substrate holder which is connected to the voltage source.

This has the advantage that the setup or the electrical connection of the device can be made very easy, because the voltage source merely has to be connected with the positive output to the substrate and with the negative output to the target.

In a further refinement, the reaction chamber comprises a housing which surrounds the target at least partially and in a contact-free manner, wherein the substrate, the reaction chamber and/or the housing form the anode.

The term “housing” here means, for example, a cathode sheet that at least partially surrounds the cathode, but is arranged spaced apart from it within the reaction chamber. Such a cathode sheet can, for example, be arranged at a defined distance from the cathode so that there is a gap between the cathode sheet and the cathode. In a case where the housing forms the anode, the process gas plasma necessary for the sputtering process is created in the space between the housing and the cathode. In this case, the housing is also coated during the coating process. The advantage is that the geometry of the housing can be freely selected and configured to the specific device. For example, a very large surface area can be provided, which is used as the anode in its entirety. Especially for HiPIMS a large anode surface is necessary for a smooth process flow.

The aforementioned refinement possibilities or aspects of the magnetron sputtering device and the advantages resulting from each of them apply in an equivalent form to the magnetron sputtering method.

In a further refinement of the herein presented method, the coating of the surface of the substrate comprises atoms of the first material and atoms of the second material, wherein the atoms of the first material are arranged in such a way with respect to the atoms of the second material that the coated surface of the substrate is electrically conductive.

The “arrangement of the atoms of the first material with respect to the atoms of the second material” in this case means the homogenization or the distribution of the atoms over the substrate surface. Advantageously, there is no surface section on the substrate surface where atoms of the first material or atoms of the second material are agglomerated. An advantageous arrangement of the atoms of the first material with respect to the atoms of the second material exists, for example, if the respective interfaces between the atoms of the first material to the atoms of the second material ensure an overall electrical conductivity of the substrate surface.

In a further refinement, the method comprises the following additional step: introducing a reactive gas into the interior of the reaction chamber, wherein the reactive gas comprises methane, acetylene, nitrogen or oxygen, and wherein reactive gas ions of the reactive gas are configured to react with atoms of the first material and/or atoms of the second material.

In this so-called “reactive sputtering” one or more reactive gases are added to the inert process gas, preferably argon. These reactive gases react at the target, in the vacuum chamber or at the substrate with the atomized atoms of the mixture and form further chemical compounds with them. The resulting reaction products are then deposited on the substrate surface.

One advantage of this method is that the layer properties of reactive sputtering can be influenced by the reactive gas inflow or the reactive gas volume flow, among other things. In addition to oxygen and nitrogen, other reactive gases such as hydrogen, steam, ammonia, hydrogen sulfide, methane or tetrafluoromethane may be used as well.

It goes without saying that the aforementioned features to be described further hereinafter may be used not only in the respectively specified combination but also in other combinations or individually without departing from the spirit and scope of the present disclosure.

### BRIEF DESCRIPTION OF THE DRAWINGS

FIG. 1 shows a schematic view of an embodiment of a magnetron sputtering device;

FIG. 2 shows a scanning electron microscope image of an exemplary mixture ZrO₂—WC;

FIG. 3 shows a light optical microscope image of the exemplary mixture of ZrO₂—WC; and

FIG. 4 shows a scanning electron microscope image of an exemplary substrate coating with a mixture ZrO₂—WC; and

FIG. 5 shows a schematic sequence of a magnetron sputtering method.

### DESCRIPTION OF PREFERRED EMBODIMENTS

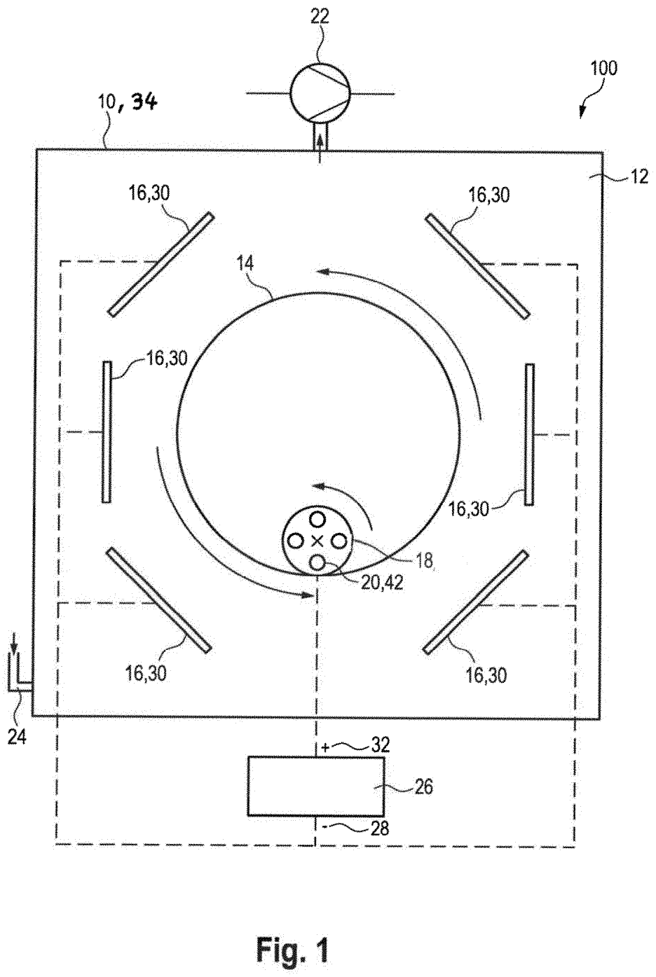

FIG. 1 shows a magnetron sputtering device according to an embodiment, wherein the magnetron sputtering device is denoted as a whole by reference numeral 100.

The magnetron sputtering device 100 comprises a reaction chamber 10, in the interior 12 of which a substrate table 14 is arranged. In the present case, the substrate table 14 is rotatable and can be set into a rotary motion by a drive motor not shown here, wherein the speed of rotation (in rpm) is controllable. The substrate table 14 may be, for example, a rotatably mounted circular metal plate.

In the present case, six targets 16 are arranged in the interior 12 of the reaction chamber 10 in an octagonal arrangement around the substrate table 14, wherein only one target would be necessary.

On the substrate table 14, a substrate carrier 18 is arranged, which in the case shown here is rotatably mounted on the substrate table 14, wherein the substrate carrier 18 is only advantageous, but does not necessarily have to be provided. The substrate carrier 18 can, for example, be configured as a basket-like device and, depending on the application, be made of an electrically conductive or electrically non-conductive material. The substrate carrier 18 is used for holding or reversibly fixing the substrate 20 during a coating process.

In the present embodiment, four substrates 20 are arranged on the substrate carrier 18. The substrates 20 can be milling heads, for example, which are to be coated in the magnetron sputtering device 100. However, only one substrate 20 needs to be present.

Target(s) 16 and substrate(s) 20 are arranged spaced apart from each other in the interior 12 of the reaction chamber 10.

In the presently shown embodiment, the reaction chamber 10 is connected to a vacuum pump 22, which is configured to create a vacuum or at least a negative pressure in the interior 12 of the reaction chamber 10 before the coating process starts. The vacuum pump 22 can be configured as a turbo pump, for example. It is used to remove reactive gas molecules, such as nitrogen and/or oxygen or air, from the interior 12 of the reaction chamber 10 before the coating process starts, thereby creating a vacuum in the interior 12.

Advantageously, an inert process gas, such as argon or another noble gas, is introduced into the interior 12 of the reaction chamber 10 via a gas inlet 24 arranged at the reaction chamber 10 to create therein an inert working atmosphere. The gas inlet 24 can, for example, be configured as a gas coupling, wherein in any case a hermetic closure of the gas inlet 24 has to be ensured.

The magnetron sputtering device 100 additionally comprises a voltage source 26, which is configured to generate a DC electric field. The voltage source 26 in FIG. 1 comprises two electrical outputs 28, 30, wherein in the herein shown illustration the negative voltage output 28 is connected to the six shown targets 16, respectively, wherein the targets 16 in the herein shown example form the cathodes 30 in the DC electric field.

The target 16 does not necessarily have to serve as cathode 30. It is also possible to use the substrate table 14 by means of a corresponding connection to the negative voltage output 28 or by means of the applied voltage as an (additional) cathode 30. For example, a target carrier (not shown here) can also be used as cathode 30.

The positive voltage output 32 of the voltage source 26 is in FIG. 1 exemplarily connected to the reaction chamber 10, whereby the reaction chamber 10 forms the anode 34 in the DC electric field. In other embodiments not shown here, the substrate carrier 18 or a device, such as e.g. one or more housing(s) for the target(s) 16, may serve as anode 34. In further applications not shown here, several anodes 34 can exemplarily be used as well. In addition, at least one anode 34 is advantageously used as ground.

The commercially available DC magnetron sputter CemeCon system, for example, can be switched against a “special” anode pair 34, which is called a “booster”. These “boosters” have a copper surface.

It should be noted that in other applications, also multiple voltage sources 26 and/or a voltage source 26 with a large number of electrical outputs and/or inputs (not shown) can be used. The voltage source(s) 26 may be configured to supply a pulsed electrical power to the cathode 30, wherein these energy pulses (i.e. the provision of the electrical power for a certain pulsed period of time) have advantageously a power>0.1 MW, preferably >0.5 MW, especially preferably >1 MW. The voltage source 26 can, for example, comprise a pulse generator and/or a pulse width modulator and is advantageously configured to generate a plurality of pulse shapes, pulse lengths and/or pulse amplitudes.

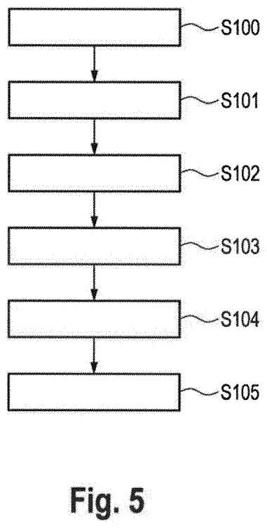

If the magnetron sputtering device 100 exemplarily shown in FIG. 1 is used for a coating process or for a magnetron sputtering method (see schematic representation in FIG. 5), the substrate 20 to be coated is provided and arranged in the substrate carrier 18 (step S100). This arrangement can be done, for example, by inserting, threading, spearing, clamping or screwing the substrate 20 into or onto the substrate carrier 18. In addition, the target 16 (in FIG. 1 six targets 16) has to be provided and arranged in the interior 12 of the reaction chamber 10 (step S101), wherein this arrangement can be done, for example, by attaching the target to a target carrier. In the present case, the substrate carrier 18 is connected to the positive voltage output 32 of the voltage source 26, whereby the target 16 forms the cathode 30 together with the target carrier which is not shown here.

The six targets 16 comprise an electrically conductive mixture 36 for coating the substrate 20, wherein the mixture 36 comprises a first material 38 and a second material 40. The first material 38 is an electrically non-conductive solid. The second material 40 is an electrically conductive solid.

The anode 34 has to be provided also in the interior 12 of the reaction chamber 10 (step S102), wherein this provision can be done, for example (as in FIG. 1), by connecting the positive voltage output 32 of the voltage source 26 to reaction chamber 10.

The substrate 20 comprises a third material 42, wherein the third material 42 is an electrically conductive solid.

When the provision and placement of the substrate 20 and the target 16 in the interior 12 of the reaction chamber 10 is complete, the reaction chamber 10 can be closed, for example, by a hermetically sealed door. As soon as the reaction chamber 10 is closed, an underpressure/vacuum is generated by the vacuum pump 22 in the interior 12 of the reaction chamber 10. Thereby, also an additional heating may be provided by a heating device (not shown here) which heats the interior 12 of the reaction chamber 10 to a process temperature. Once the vacuum has been generated, the process gas is introduced into the interior 12 of the reaction chamber 10 via the gas inlet 24 (step S103) and an DC electric field is generated between the cathode 30 and the anode 34 by the voltage source 26 (step S104).

The DC electric field generated by the voltage source 26 causes an impact ionization of atoms of the process gas, in which the atoms of the process gas are divided into negatively charged electrons and positively charged process gas ions, wherein the positively charged process gas ions are accelerated by the applied DC field towards the target 16. When the process gas ions collide with the surface of the target 16, atoms of the mixture 36 are released by a pulse transfer, which atoms move from the target 16 towards the substrate 20 and coat a surface of the substrate 20 (step S105). During this coating process, the substrate 20 can be moved, for example, by a rotary movement of the substrate table 14 and an additional relative rotary movement of the substrate carrier 18 in the interior 12 of the reaction chamber 10.

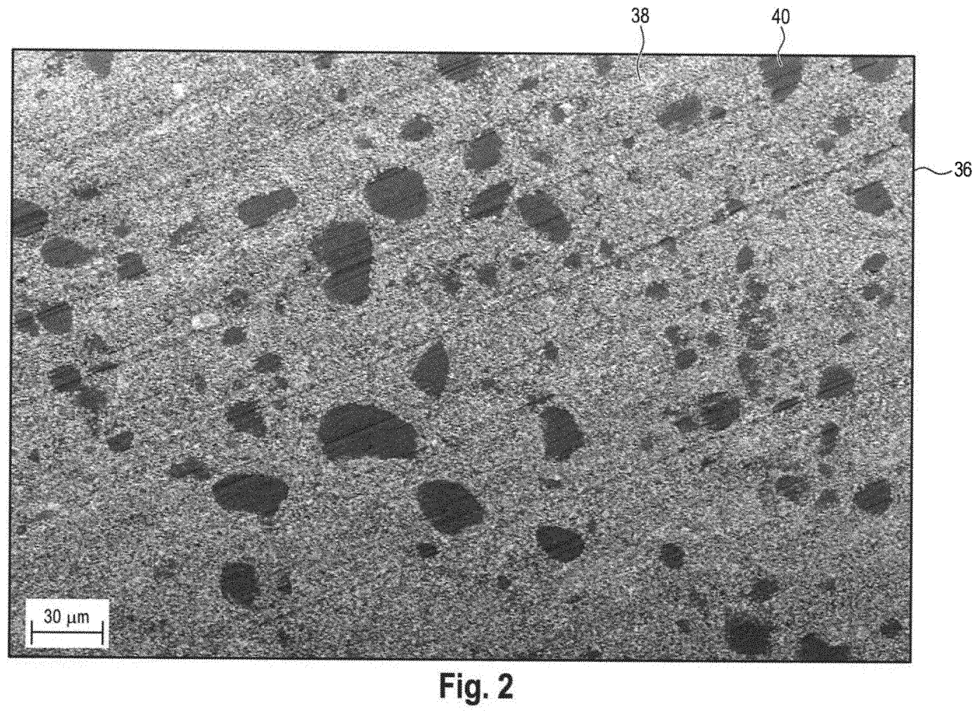

FIG. 2 shows a scanning electron microscope image of the surface of an exemplary target 16, which contains the electrically conductive mixture 36, which in the case shown herein is ZrO₂—WC.

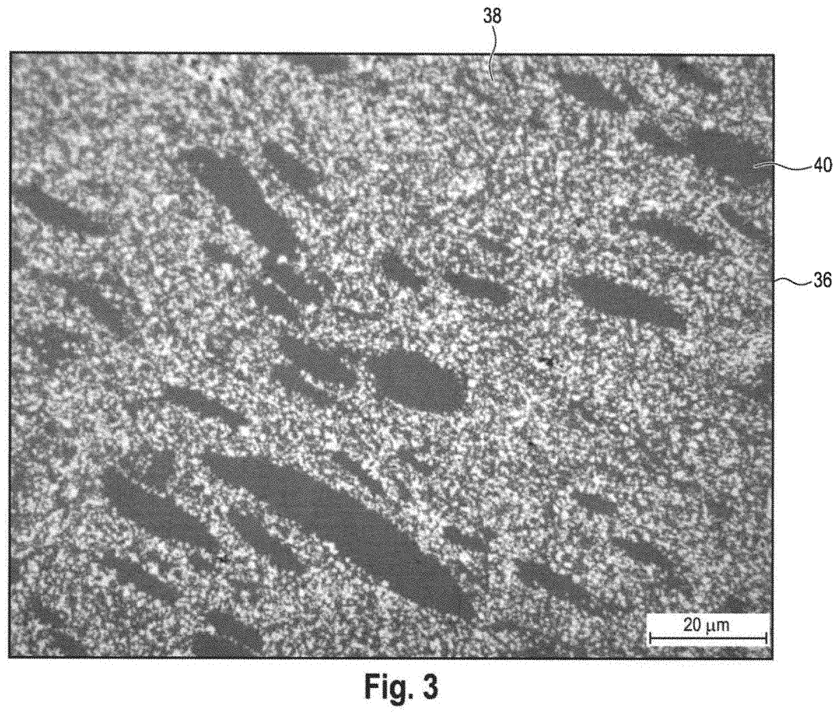

FIG. 3 shows a corresponding light optical microscope image of the mixture 36. The mixture 36 consists of the first electrically non-conductive material 38 (here zirconium oxide (ZrO₂)) and the second electrically conductive material 40 (here tungsten carbide (WC)). Advantageously, the first material 38 has a first volumetric portion ΔV₁ and the second material 40 has a second volumetric portion ΔV₂, wherein the following applies advantageously: ΔV₁≥ΔV₂, preferably ΔV₁≥1.5 ΔV₂.

From FIGS. 2 and 3 it may be observed that the second material 40 or tungsten carbide is dark and the first material 38 (here zirconium oxide (ZrO2)) is light. The target 16 can, for example, be produced by hot pressing or a sintering process. Depending on the manufacturing process and the production sequence, smaller or larger microstructure components are produced in the mixture 36.

In the most general case, the first material 38 can be an electrically non-conductive solid. It is advantageous if the first material 38 is a first inorganic solid. It is also advantageous if the first inorganic solid is a carbide, an oxide and/or a nitride, more advantageously a metal oxide. It is particularly advantageous if the metal oxide is ZrO₂, Al₂O₃ or TiO₂. The second material 40 can in the most general case be an electrically conductive solid. It is advantageous if the second material 40 is a second inorganic solid. It is also advantageous if the second inorganic solid is an elemental metal, a boride, a carbide, and/or a nitride, more advantageously a carbide. It is particularly advantageous if the carbide is WC, NbC, HfC, TaC, TiC, MoC and/or Cr₃C₂.

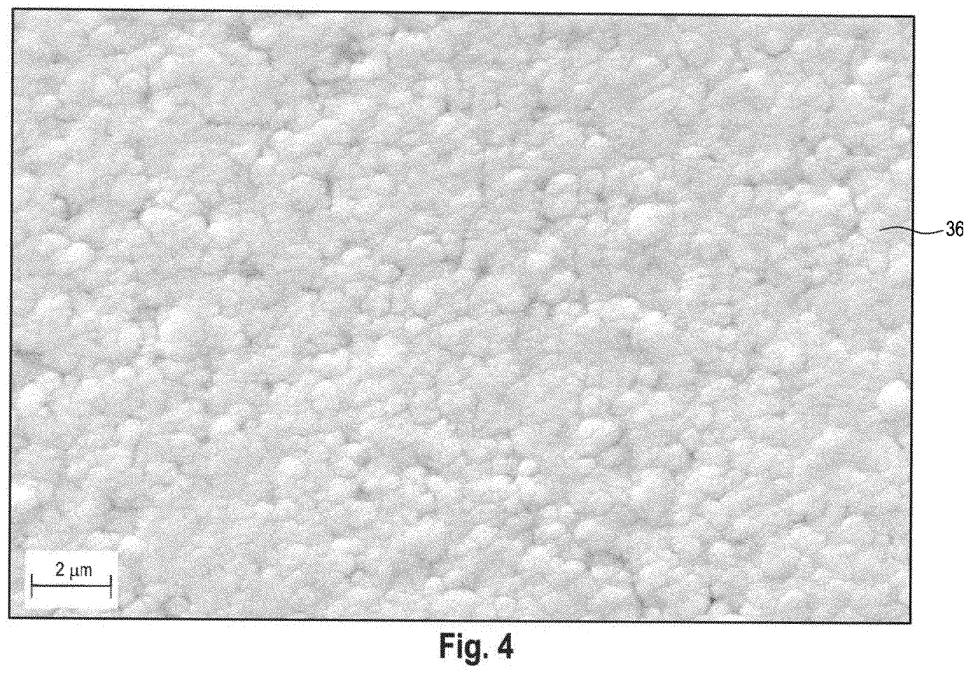

FIG. 4 shows a scanning electron microscope image after coating substrate 20 with ZrO₂—WC. The ZrO₂—WC layer was deposited on the surface of substrate 20, with substrate 20 having the third material 42. Advantageously, the third material 42 is carbide, cermet, cubic boron nitride or steel.

The applicant carried out eight exemplary coating processes, the process steps of which are shown below with the respective process-specific parameters in Table 1. For the deposition of the mixture 36 on the substrate 20, a coating system of the CC800/HiPIMS type from CemeCon AG with a rotating substrate carrier 18 was used (see simplified in FIG. 1). The process step “coating” (see Table 1) was performed at different high energy pulse frequencies and pulse lengths, the resulting coating properties are shown in Table 2.

TABLE 1
Process flow of an embodiment of the coating
process (magnetron sputtering method)

| Process phase | Process step | Measurement/Unit | | Time |
|---|---|---|---|---|
| Heating phase 1 | pressure when heating is started | 3 | mPa | 3.000 s |
| | Heating power heating unit 1 | 9 | kW | |
| | Heating power heating unit 2 | 14 | kW | |
| | Turbopump performance | 100% | | |
| | Table rotation | 0.33 | rpm | |
| heating phase 2 | Heating power heating unit 1 | 9 | kW | 1.200 s |
| | Heating power heating unit 2 | 14 | kW | |
| | Turbopump performance | 66% | | |
| | Table rotation | 0.33 | rpm | |
| | Print test limit | 4 | mPa | |
| Etching phase 1 | Heating power heating unit 1 | 9 | kW | 1.200 s |
| | Heating power heating unit 2 | 14 | kW | |
| | Turbopump performance | 66% | | |
| | Table rotation | 1.00 | rpm | |
| | MF bias voltage | −650 | V | |
| | Frequency | 240 | kHz | |
| | Argon pressure | 350 | mPa | |
| Etching phase 2 | Heating power heating unit 1 | 9 | kW | 3.600 s |
| | Heating power heating unit 2 | 14 | kW | |
| | Turbopump performance | 66% | | |
| | DC bias voltage | −200 | V | |
| | Plasma Booster Current | 20 | A | |
| | Argon Flow | 250 | mln | |
| | Krypton Flow | 190 | mln | |
| | Table rotation | 1.00 | rpm | |
| Coating | Heating power heating unit 1 | 9 | kW | see table 2 |
| | Heating power heating unit 2 | 14 | kW | |
| | Turbopump performance | 66% | | |
| | Table rotation | 1.00 | rpm | |
| | Argon Flow | 650 | mln | |
| | HiPIMS frequency | See Table 2 | | |
| | HiPIMS pulse length | See Table 2 | | |
| | HiPIMS table Bias voltage | −70 | V | |
| | HiPIMS table pulse length | 40 | μs | |
| | HiPIMS table pulse offset | 20 | μs | |
| | Cathode power | 4.5 | kW | |
| Cooling | Ventilation temperature | 180° | C. | 1.800 s |
| | Turbopump performance | 66% | | |
| | Table rotation | 1.00 | rpm | |

TABLE 2
Variation of frequency and pulse length of high energy pulses
in a exemplary high-energy pulse magnetron sputtering processes
and their Influence on the substrate coating.

| | Pulse | | | Young's | Coating |
|---|---|---|---|---|---|
| Frequency | length | Time | Hardness | modulus | thickness |
| [Hz] | [μs] | [s] | [GPa] | [Gpa] | [μm] |
| 400 | 40 | 18000 | 21.8 | 410 | 1.5 |
| 500 | 40 | 18000 | 22.7 | 400 | 1.7 |
| 800 | 40 | 18000 | 22.0 | 380 | 1.9 |
| 1000 | 40 | 18000 | 22.5 | 420 | 2.0 |
| 2000 | 40 | 18000 | 22.8 | 380 | 2.4 |
| 2000 | 70 | 10800 | 22.5 | 420 | 1.5 |
| 2500 | 60 | 10800 | 21.5 | 440 | 1.8 |
| 4000 | 40 | 18000 | 21.7 | 350 | 2.5 |

In the processes to be described, 16 copper plates were used as targets, which were equipped with soldered-on ceramic plates (consisting of the mixture 36, with the first material 38 and second material 40). The ceramic plates were produced by hot pressing of yttrium-stabilized zirconium oxide powder (first material 38) and tungsten carbide powder (second material 40).

At the beginning of the respective process, a first heating phase (heating phase 1) was carried out in which the vacuum pump 22 or turbopump was operated at full capacity to generate the vacuum. This full capacity utilization of the turbopump is necessary because during the heating process, i.e. when heating the materials from room temperature to operating temperature, material-bound gas atoms (e.g. in the mixture or similar) are outgassed within the reaction chamber 10, which is why the turbopump has to remove a larger amount of free molecules from the reaction chamber. After 3000 seconds, the second heating phase (heating phase 2) followed, during which the turbopump was operated at 66% of its capacity. This second heating phase is advantageous to ensure complete heating of the targets 16 and the substrate 20 or to stabilize the process temperature.

After 1200 seconds a first etching phase followed, which is also known to the skilled person as “medium frequency etching”. Here, the substrate 20 is subjected to a bias voltage that is high compared to the cathode voltage. This high negative bias voltage causes more process gas ions to strike the substrate surface than the target surface. The surface of the substrate 20 is thus freed from impurities and additionally roughened for the later coating process, which improves the coating adhesion. The first etching phase lasted 1200 seconds.

The first etching phase was followed by the second etching phase for a duration of 3600 seconds. Here argon and krypton were introduced into the reaction chamber 10 and brought into an ionized state (in the form of an ion beam) by an additional plasma booster current. This second etching phase is particularly advantageous for substrates 20 with a large number of edges, since the edges are only slightly cleaned or roughened during the first etching phase. The “argon ion etching” leads to a better adhesion of the layer on the substrate surface, wherein the ion beam can clean or roughen the multitude of edges of the substrate.

After the etching phase, the process step “coating” was carried out, wherein both the frequency and the pulse length of the high-energy pulses were varied. Here, the thickness of the coating can be influenced by adjusting deposition parameters such as HiPIMS frequency, HiPIMS pulse width, temperatures, bias voltage, flow rates of the introduced gases as well as the quantity of the operated targets 16.

For example, with a HiPIMS frequency of 2000 Hz, a pulse length at the cathodes of 40 μs and a coating time of 18000 s, a substrate coating with a layer thickness of 2.4 μm, a hardness of 22.8 GPa and a Young's modulus of 380 GPa was produced. In another exemplary coating process, a substrate coating with a layer thickness of 1.8 μm, a hardness of 21.5 GPa and a Young's modulus of 440 GPa was produced with a HiPIMS frequency of 2500 Hz, a pulse length at the cathodes of 60 μs and a coating time of 10800 s (see Table 1).

Hardness and modulus of elasticity (Young's modulus) were measured by nanoindentation in the unit GPa. In this measuring method, a diamond test piece, which has a three-sided pyramid shape, is pressed into the layer and a force-displacement curve is recorded. From this curve, the mechanical properties of the layer can be determined using the Oliver-Pharr method. An NHT1 from CSM, Switzerland, was used for nanoindentation.

As a final process step, a cooling step was performed, wherein the reaction chamber 10 was cooled by aeration.

It should be explicitly mentioned at this point that the process phases explained above (heating phase 1, heating phase 2, etching phase 1, etching phase 2 as well as cooling) are merely advantageous, but do not necessarily have to be carried out with the magnetron sputtering device 100 and method presented herein.

What is claimed is:

1. A magnetron sputtering device comprising:
a substrate;
a sintered or hot-pressed target which forms a cathode in a DC electric field and comprises an electrically conductive mixture for coating the substrate;
an anode in the DC electric field;
a reaction chamber in which the target and the substrate are arranged, wherein the target is arranged spaced apart from the substrate; and
a voltage source configured to generate the DC electric field between the cathode and the anode;
wherein the mixture comprises a first material and a second material, wherein the first material is an electrically non-conductive solid, and wherein the second material is an electrically conductive solid selected from the group consisting of a boride, a carbide, a nitride, and mixtures thereof; and
wherein the substrate comprises a third material which is an electrically conductive solid.

2. The magnetron sputtering device according to claim 1, wherein the first material has a first volumetric portion ΔV₁ and the second material has a second volumetric portion ΔV₂, wherein it applies: ΔV₁≥ΔV₂, preferably ΔV₁≥1.5 ΔV₂.

3. The magnetron sputtering device according to claim 1, wherein the first material is a first inorganic solid.

4. The magnetron sputtering device according to claim 1, wherein the first material is selected from the group consisting of a carbide, an oxide, a nitride, and mixtures thereof.

5. The magnetron sputtering device according to claim 1, wherein the first material is a metal oxide.

6. The magnetron sputtering device according to claim 1, wherein the first material is selected from the is ZrO₂, Al₂O₃ or TiO₂

7. The magnetron sputtering device according to claim 1, wherein the second material is a carbide.

8. The magnetron sputtering device according to claim 1, wherein the second material is selected from the group consisting of WC, NbC, HfC, TaC, TiC, MoC, Cr₃C₂ and mixtures thereof.

9. The magnetron sputtering device according to claim 1, wherein the third material is selected from the group consisting of a carbide, cermet, cubic boron nitride and steel.

10. The magnetron sputtering device according to claim 1, wherein the voltage source (26) is configured to generate a pulsed electrical power that is supplied to the cathode.

11. The magnetron sputtering device according to claim 10, wherein the voltage source is configured to generate energy pulses with a power larger than 0.1 MW.

12. The magnetron sputtering device according to claim 1, wherein the voltage source is configured to apply a negative bias voltage to the substrate.

13. The magnetron sputtering device according to claim 1, wherein the substrate forms the anode.

14. The magnetron sputtering device according to claim 1, wherein the reaction chamber comprises a housing which surrounds at least a part of the target and is not in contact with the target, wherein the substrate, the reaction chamber and/or the housing form the anode.

15. A magnetron sputtering method comprising:
providing a substrate;
providing a sintered or hot-pressed target which forms a cathode in a DC electric field and comprises an electrically conductive mixture for coating the substrate, wherein the mixture comprises a first material and a second material, wherein the first material is an electrically non-conductive solid, and wherein the second material is an electrically conductive solid from the group consisting of a boride, a carbide, a nitride, and mixtures thereof;
providing an anode in the DC electric field;
arranging the target and the substrate in a reaction chamber, wherein the target is arranged spaced apart from the substrate, wherein the substrate comprises a third material, wherein the third material is an electrically conductive solid;
introducing a process gas into the reaction chamber; and
generating the DC electric field between the cathode and the anode.

16. The magnetron sputtering method according to claim 15, wherein the first material has a first volumetric portion ΔV₁ and the second material has a second volumetric portion ΔV₂, wherein ΔV₁≥ΔV₂.

17. The magnetron sputtering method according to claim 15, further comprising:
causing an impact ionization of atoms of the process gas by the DC electric field that is generated by the voltage source, wherein the impact ionization divides the atoms of the process gas into negatively charged electrons and positively charged process gas ions,
accelerating the positively charged process gas ions towards the target by the applied DC electric field,
releasing atoms from the mixture by a pulse transmission upon impact of the process gas ions on the target,
moving the released atoms from the target towards the substrate, and
coating a surface of the substrate with the released atoms.

18. The magnetron sputtering method according to claim 17, wherein the released atoms include atoms of the first material and atoms of the second material, wherein the coating of the surface is performed such that the atoms of the first material are arranged with respect to the atoms of the second material in such a way that the coated surface of the substrate is electrically conductive.

19. The magnetron sputtering method according to claim 15, comprising:
introducing a reactive gas into the reaction chamber, wherein the reactive gas is selected from the group consisting of methane, acetylene, nitrogen and oxygen, and wherein reactive gas ions of the reactive gas are configured to react with atoms of the first material and/or atoms of the second material.

20. The magnetron sputtering method according to claim 15, wherein only a process gas but no reactive gas is introduced into the reaction chamber.
